(19) United States
(12) Patent Application Publication
(10) Pub. No.: US 2012/0052321 A1
(43) Pub. Date: Mar. 1, 2012

(54) SANITARY OBJECTS

(76) Inventor: Karl THOMAS, Menden (DE)

(21) Appl. No.: 13/291,606

(22) Filed: Nov. 8, 2011

Related U.S. Application Data
(63) Continuation of application No. PCT/EP2010/002803, filed on May 7, 2010.

(30) Foreign Application Priority Data
May 8, 2009 (DE) 10 2009 020 500.4

(51) Int. Cl. B32B 15/04; C23C 16/44; B32B 3/10; C23C 16/06; B32B 15/20; B32B 18/00

(52) U.S. Cl. 428/623; 428/457; 428/336; 428/450; 428/446; 428/469; 428/201; 428/632; 427/250

(57) ABSTRACT

A sanitary object having a decorative surface, which comprises substantially a body, formed of plastic or metal and an at least partial outer coating, that at least one metal layer has a combination of at least two elements selected from the following group: aluminum, chromium, zinc, silver, titanium, and/or zirconium, and is arranged as a coating.

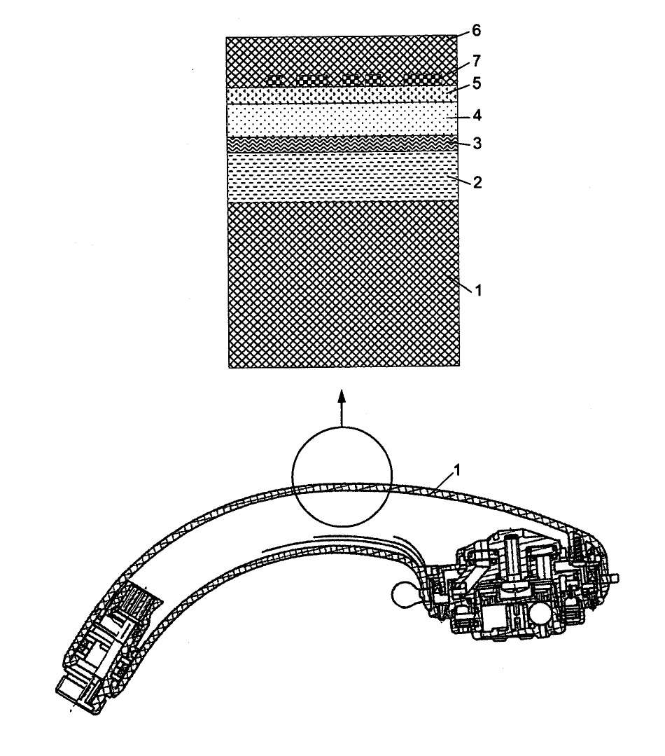

This nonprovisional application is a continuation of International Application No. PCT/EP2010/002803, which was filed on May 7, 2010, and which claims priority to German Patent Application No. DE 10 2009 020 500.4, which was filed in Germany on May 8, 2009, and which are both herein incorporated by reference.

### BACKGROUND OF THE INVENTION

1. Field of the Invention

The invention relates to sanitary objects with a decorative surface structure and a method for the production thereof.

2. Description of the Background Art

In the case of many articles of daily use, particularly sanitary objects, apart from their technical function their design plays a decisive role. In this regard, the configuration of the surface is very important. In regard to sanitary fittings, showerheads, handheld showerheads, bathroom accessories, lights, shelving, etc., it is generally desirable that the surfaces are metallic or have a metallic nature. Apart from sanitary objects made of metal, which are provided with a galvanic coating, these objects are often made of plastic, which are provided with metallic covering layers.

The metallic covering layers have the mentioned decorative function, on the one hand, but must also be resistant to corrosion, friction, and chemical attack.

In the case of sanitary objects, galvanic chrome plating is frequently provided for the desired metallic covering layers. This means that the sanitary objects are given a final chrome surface, which can be made glossy or matte as desired.

Numerous methods for applying decorative layers are known from the state of the art, however. Apart from wet chemical methods, such as galvanic processes, methods are known such as PVD (physical vapor deposition), CVD (chemical vapor deposition), and coating methods and combinations thereof, by means of which layers with a specific coloring can be deposited on the objects.

Because of regulatory provisions, galvanic chrome platings in sanitary objects are problematic, however, because contact of water with chrome-plated surfaces, which has a nickel and a chromium layer, is to be avoided to prevent entry of nickel into drinking water. In wet chemical processes, however, entry of nickel into the interior of water-carrying parts can hardly be prevented. For this reason, sanitary objects, particularly handheld showerheads, which is formed of chrome-plated plastic, are typically made as two pieces. The outer housing formed of chrome-plated ABS plastic, has only decorative purposes. The internal water conduits can be formed of plastic, which meets legal requirements in regard to drinking water compliance.

In addition, thermoplastics specifically, such as acrylonitrile-butadiene-styrene (ABS), which is suitable for chrome plating, are not permitted as water-carrying parts, because during their use compliance with legally mandated limits for certain water-soluble substances is not possible.

German Offenlegungsschrift No. DE 10 2005 026 633 A1, which corresponds to U.S. Pat. No. 8,011,100, discloses a method for the preparation of galvanized sanitary objects made of plastic, in which chrome or nickel plating of water-carrying areas is said to be avoided through decoupling of these areas from the current flow by means of additional parts.

### SUMMARY OF THE INVENTION

It is therefore an object of the invention to improve the production of water-carrying, single-piece sanitary objects with a decorative surface.

A sanitary object comprising a substrate and a coating is provided by the invention, whereby the substrate has plastic or metal, particularly brass, zinc, or stainless steel, and the coating has a metal layer made of a combination of at least two elements selected from the group comprising aluminum, chromium, zinc, silver, titanium, and zirconium. Coating is understood to be the application of a firmly adhering layer of a formless substance to a workpiece. The layer and substrate form a composite body made of different substances. The layer assumes the contact function, such as protection against chemical or corrosive attack and against tribological stress, influences the frictional behavior, or is used for visual or decorative purposes, whereas the substrate assumes the support function or media supplying, whereby its properties can be adapted to the specific stress without consideration of the contact behavior.

A body, which may be water-carrying, is produced from the substrate by means of casting methods, shaping methods, or in the case of plastics by means of injection molding methods.

Next, the metal layer is produced by a PVD method at least on the outer surface of the body. In so doing, a target can be used, which includes an alloy of at least two elements selected from the group comprising aluminum, chromium, zinc, silver, titanium, and zirconium. Alternatively, targets may be used, which includes the single elements, so that the alloy composition of the metal layer is realized directly during the deposition. It is possible thereby to change the element portions in the alloy during the coating process. This has the result that layer properties, particularly the color, can be changed with the layer thickness and the layer profile.

The appearance of a chrome surface, produced by a galvanic process, can be reproduced by the suitable combination of the material portions in the metal layer, as well as process parameters and process management. Just like typical parts produced by galvanic processes, the sanitary object of the invention has an excellent chemical resistance to solvents and cleaning agents, a igh light reflection, and a high-gloss surface.

The metal layer can be made sufficiently thick, so that it is opaque or totally reflective. In this case, the metal layer preferably has a thickness of 40 to 150 nm.

Alternatively, the metal layer can also be made with translucent or semitransparent properties. This can be achieved with a layer thickness of 15 to 40 nm, preferably 25 nm. In this regard, the layer can be backlit from one side, for example, from the substrate side.

Additional property advantages are achieved by the application of multiple layers.

According to an embodiment of the invention, the sanitary object can have an intermediate layer or a buffer layer between the body and the metal layer in the form of an organic layer, metallic layer, metallic layer sequence, or a layer sequence comprising at least one organic and one metallic layer. The intermediate layer or buffer layer is used to balance different mechanical and chemical properties of the water-carrying body and metal layer or layer system. Otherwise, there is the danger of layer failure due to crack formation. Advantageously, the metallic layer of the intermediate layer or buffer layer of one element or a combination of several elements selected from the group comprising zirconium, titanium, chromium, tin, and zinc is provided. As a result, the interfaces (between the intermediate layer and body and between the intermediate layer and metal layer) very advantageously have chemical compounds, with whose help chemical bonding bridges are created, as a result of which better adherence of the metal layer on the intermediate layer compared with the water-carrying body is assured. Further, the intermediate layer has a greater surface roughness than the body, so that during direct metallization by the PVD method a mechanical interlocking between the intermediate layer and the metal layer is achieved, as a result of which the adherence of the metal layer is also improved. Advantageously, the metallic layer of the intermediate layer has a thickness of 10 to 60 nm.

An embodiment of the invention provides that a layer sequence comprising an organic and metallic layer is arranged between the water-carrying body and the metal layer, whereby the organic layer is adjacent to the water-carrying body. The organic layer or primer, which can be applied by means of a coating technique, is used as the leveling layer. Depending on the extent of the surface treatment of the water-carrying body, it has a smoothed, polished, or intentionally structured surface. Further, the organic layer serves as a coupling layer or coupling agent between the water-carrying body and the metal layer. The intermediate layer thereby again balances the different mechanical and chemical properties of the water-carrying body and metal layer or layer system.

A refinement of the invention provides in addition that a covering layer in the form of an inorganic layer, an additional organic layer, or a layer sequence comprising an inorganic and an organic layer is applied as a final layer.

Advantageously, in this case, a ceramic hard material layer, preferably comprising AlSiₓO_{y}N_{z}, AlOₓN_{y}, Al₂O₃, or SiO₂, is applied as a covering layer or part of a covering layer to the metal layer using a PVD method. This hard material layer represents a scratch protection layer on the color-imparting metal layer. It functions in addition as a barrier layer or diffusion protection layer, as a result of which the chemical resistance of the metal layer lying beneath it is increased. This hard material layer may have a layer thickness of 10 to 200 nm.

In sanitary objects in particular, which are often provided with a representative logo or lettering, it is an advantage when a marking layer is provided below the covering layer at least in sections. Said marking layer can be a decorative layer or has only symbols or letters, which are used for information. The final transparent covering layer protects the thereby possible lettering from wear by cleaning agents, etc.

Further scope of applicability of the present invention will become apparent from the detailed description given hereinafter. However, it should be understood that the detailed description and specific examples, while indicating embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawing which is given by way of illustration only, and thus, is not limitive of the present invention, and wherein the figure shows a cross section through a handheld showerhead with a layer structure of the invention.

### DETAILED DESCRIPTION

The handheld showerhead shown in the figure has a base material or substrate of plastic. The water conduits, showerhead, and handle are produced as a single piece, for example, in an injection molding method. An intermediate layer or buffer layer in the form of a layer sequence comprising an organic layer 2 and a metallic layer 3 is arranged on the surface of the water-carrying body. This is followed by a glossy or metal layer 4 of a combination of at least two elements selected from the group comprising aluminum, chromium, zinc, silver, titanium, and zirconium. For example, very good color results and high corrosion resistance were achieved with an alloy of aluminum, chromium, and silver and an alloy of aluminum, chromium, silver, and zirconium. In addition, these alloys have very good balancing properties relative to the substrate, so that no cracks occurred after the coating.

A covering layer is applied to the glossy or metal layer 4 in the form of a layer sequence of an inorganic layer 5 and a final organic layer 6, a so-called top coat coating. In this layer sequence, inorganic layer 5 serves as a bonding bridge, because some metal layers typically have poor adherence properties relative to coating layers. Whereas metal layer 4 is to assure the corrosion resistance of the coated object, the covering layer is used to increase scratch resistance. The desired color of the overall appearance of the particular object is created, moreover, by the covering layer in combination with metal layer 4. In this way, not only the desired ‘chrome color’, which can be achieved otherwise only by galvanic methods, but a different coloring and structures with a metallic impression, matting, and metallic effects can also be created. Overall, the covering layers assume a protective function; they are scratch-resistant, anticorrosive, anti-adherent, and dirt-repelling.

For the substrate of the water-carrying body, a plastic can be selected that meets the legal requirements for potable water quality. No specific type of plastic is needed for the layer structure of the invention. Because all layers can be applied from the outside, the interior of the handheld showerhead remains uncoated. Contact of the drinking water with the external layer system or entry of soluble substances from the coating into the water passed through the sanitary object does not occur.

The lifetime of the sanitary objects of the invention as well is lengthened by the novel coating. Whereas crack formations in the surface occur often in known single-piece galvanized sanitary objects, because plastic and the galvanic layer react differently to thermal stress, damage due to different tensions does not occur owing to the thin coating of the sanitary objects of the invention. The PVD layers are made so thin relative to the substrate of the water-carrying body that no internal stresses occur within the layer.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A sanitary object having a decorative surface, the sanitary object comprising:
a body formed of plastic, metal, brass, zinc, or stainless steel;
an at least partial outer coating formed of a metal layer having a combination of at least two elements selected from: aluminum, chromium, zinc, silver, titanium, and/or zirconium; and
a covering layer provided as an inorganic layer, an organic layer, or as a layer sequence of at least one inorganic and one organic layer, wherein a ceramic hard material layer is applied by a physical vapor deposition method as the covering layer or part of the covering layer on the metal layer.

2. The sanitary object according to claim 1, wherein the metal layer is translucent or semitransparent.

3. The sanitary object according to claim 1, wherein the metal layer has a thickness of 15 to 40 nm.

4. The sanitary object according to claim 1, wherein the metal layer has a thickness of 40 to 150 nm.

5. The sanitary object according to claim 1, wherein an intermediate layer is arranged between the substrate and the metal layer as an organic layer, metallic layer, metallic layer sequence, or a layer sequence of at least one organic and at least one metallic layer.

6. The sanitary object according to claim 5, wherein the metallic layer of the intermediate layer of one element or a combination of several elements selected from zirconium, titanium, chromium, tin, and/or zinc is provided.

7. The sanitary object according to claim 5, wherein an organic layer of the intermediate layer is arranged adjacent to the water-carrying body.

8. The sanitary object according to claim 1, wherein an inorganic layer for the covering layer is provided as a transparent, ceramic hard material layer comprising AlSiₓO_{y}N_{z}, AlOₓN_{y}, Al₂O₃, or SiO₂.

9. The sanitary object according to claim 1, wherein below the covering layer, a marking layer is provided in sections.

10. The sanitary object according to claim 5, wherein the metallic layer of the intermediate layer has a thickness of 10 to 60 nm.

11. The sanitary object according to claim 1, wherein the ceramic hard material layer of the covering layer has a thickness of 10 to 200 nm.

12. A method for the production of sanitary objects with decorative surfaces, the method comprising:
applying a firmly adhering layer to a body made of plastic, metal, stainless steel, zinc, or brass;
applying a metal layer by physical vapor deposition to the body, the metal layer being a combination of at least two elements selected from: aluminum, chromium, zinc, silver, titanium, and/or zirconium; and
applying a covering layer in the form of an inorganic hard material layer, another organic layer, or a layer sequence of at least one inorganic and one organic layer.

13. The method according to claim 13, wherein, before the application of the metal layer, at least one organic layer, metallic layer, metallic layer sequence, or a layer sequence of at least one organic and at least one metallic layer is applied to the water-carrying body.
